(19) United States
(12) Patent Application Publication
(10) Pub. No.: US 2021/0367195 A1
(43) Pub. Date: Nov. 25, 2021

(54) METHOD FOR ENCAPSULATING OLED, OLED DEVICE AND DISPLAY DEVICE

(71) Applicant: Xianyang Caihong Optoelectronics Technology Co.,Ltd, XIANYANG (CN)

(72) Inventors: QIZHE CAI, XIANYANG (CN); MIAOMIAO FAN, XIANYANG (CN)

(21) Appl. No.: 17/239,999

(22) Filed: Apr. 26, 2021

(30) Foreign Application Priority Data
May 19, 2020 (CN) 2020104241356
May 19, 2020 (CN) 2020104241430

(51) Int. Cl. H01L 51/52; H01L 51/56; H01L 27/32

(52) U.S. Cl. CPC H01L 51/5246; H01L 27/3246; H01L 51/5253; H01L 51/56

(57) ABSTRACT

A method for encapsulating an OLED, an OLED device and a display device are provided. The method includes: providing a cover plate; providing a substrate, where a side of the substrate is provided with an OLED unit; and forming a water-oxygen-blocking encapsulation structure between the cover plate and the substrate based on a silane coupling agent, where the water-oxygen-blocking encapsulation structure coats the OLED unit. Through forming the water-oxygen-blocking encapsulation structure coating the OLED unit between the cover plate and the substrate, the water-oxygen-blocking capability of the OLED device is improved, the material limitation problem which takes into account the requirements of high adhesion and excellent water and oxygen blocking capability is effectively solved, and the thinning the display device is expected to be realized.

### TECHNICAL FIELD

The disclosure relates to the technical field of an organic light-emitting diode (OLED), and in particular to a method for encapsulating an OLED, an OLED device and a display device.

### DESCRIPTION OF RELATED ART

With the continuous improvement of people's living standards, market requirements of large-scale, ultra-thin and flexible health intelligent display technology for display panels and lighting systems will gradually become urgent requirements of people's lives. A demand for a Liquid-crystal display (LCD) panel throughout the world is stagnant, thereby facing the crisis of overcapacity.

A new display technology has become the focus of research and development of major companies, in which an organic light-emitting diode (OLED) has been widely concerned by the scientific community and developed rapidly due to its advantages of low driving voltage, high efficiency, fast response speed, wide viewing angle, lightness, large area and flexible display. An OLED display device is considered as a new application technology of the next generation flat panel display since it has advantages of self-illumination, no requirement of backlight, high contrast, thin thickness, wide viewing angle, fast response speed, and application to flexible panel, and the like.

At present, the OLED display device is usually manufactured by a vacuum evaporation technology and a printing technology and the OLED display device and a quantum dot light emitting diode (QLED) display device are manufactured by solution processing. Therefore, since the above display devices have advantages of low cost, high yield and easy realization of large size, they become an important development tendency of display technology in the future. Further, the printing technology is considered to be the most effective way to realize low-cost and large-area full-color display of the OLED display device and the QLED display device.

A main factor that restricts the development of the OLED industry and a main defect of the OLED display device is its short life, the main reason for which is that an organic material constituting electrodes and a luminescent layer of the OLED display device is very sensitive to pollutants, water vapor and oxygen in the atmosphere, and is prone to electrochemical corrosion in the environment containing water vapor and oxygen, and thereby a damage to the OLED display device is caused.

Furthermore, a moisture permeability (water vapor transmission rate, WVTR) of the OLED display device needs to reach 10⁻⁶ g/m²·day to slow down the influence of water and oxygen, while a barrier effect of a frame encapsulating material of the OLED display device on water and gas or pollutants is limited. For a rigid encapsulation, water and oxygen are prone to invade the OLED display device from a side thereof, such that the OLED display device is damaged due to the action of water and oxygen, thereby resulting in accelerated aging and failure of the OLED display device.

An existing encapsulating material of the OLED display device usually includes an inorganic filler and a few millimeters of frame for encapsulating the OLED display device an thus isolating water and oxygen. However, more and more products need to have features of “ultra-thin” and “narrow frame”.

### SUMMARY

To overcome at least some defects and deficiencies in related technologies, embodiments of the disclosure provide a method for encapsulating an OLED, an OLED device and a display device.

A method for encapsulating an OLED is provided, including: providing a cover plate; providing a substrate, where a side of the substrate is provided with an OLED unit, forming a water-oxygen-blocking encapsulation structure between the cover plate and the substrate based on a silane coupling agent, where the water-oxygen-blocking encapsulation structure coats the OLED unit.

In an embodiment of the disclosure, forming a water-oxygen-blocking encapsulation structure between the cover plate and the substrate based on a silane coupling agent, includes: forming a first surface treatment agent layer with a first chemical group on a lower surface of the cover plate; and forming a second surface treatment agent layer with a second chemical group on an upper surface of a laminated structure formed by the substrate and the OLED unit; the first chemical group of the first surface treatment agent layer chemically reacts with the second chemical group of the second surface treatment agent layer to thereby form the water-oxygen-blocking encapsulation structure.

In an embodiment of the disclosure, the upper surface includes an outer surface of a pixel definition layer of the substrate; the first chemical group at least includes one of —NCO, —NH2 and —OH, and the second chemical group at least includes one of —OH and —NH2.

In an embodiment of the disclosure, the outer surface of the pixel definition layer includes an upper surface of the pixel definition layer and an outer side surface of the pixel definition layer; the first surface treatment agent includes the silane coupling agent; and the second surface treatment agent includes a silicon-nitrogen compound (SiNx) and/or a silicon-oxygen compound.

In an embodiment of the disclosure, the method further includes: adding a layer of silane coupling agent to the outer surface of the pixel definition layer, so as to enable a hydrogen bonding between a —NH2/—OH group of the silicon-nitrogen compound/silicon-oxygen compound and an —X group of the X—Si(OR)3 to thereby enhance an adhesion force of the water-oxygen-blocking encapsulation structure.

In an embodiment of the disclosure, the water-oxygen-blocking encapsulation structure includes a sealant and a side surface treatment layer; forming a water-oxygen-blocking encapsulation structure between the cover plate and the substrate based on a silane coupling agent, includes: forming the sealant between the cover plate and the substrate to coat the OLED unit; and forming the side surface treatment layer on an outer side surface of the sealant.

In an embodiment of the disclosure, the side surface treatment layer includes the silane coupling agent; the side surface treatment layer is formed on the outer side surface of the sealant by a coating process.

In an embodiment of the disclosure, a thickness of the side surface treatment layer is in a range from in a range from 10 nanometers (nm) to 30 nm, and a hydrophobic group of the silane coupling agent at least includes one of a long alkyl and a long alkyl epoxy ethyl.

In another respect, an embodiment of the disclosure also provides an OLED device using the above method, and the OLED device includes: a cover plate; a substrate, opposite to the cover plate; an OLED unit, arranged on a side of the substrate facing towards the cover plate; and a water-oxygen-blocking encapsulation structure based on a silane coupling agent, formed between the cover plate and the substrate and coating the OLED unit.

In an embodiment of the disclosure, a lower surface of the cover plate is provided with a first surface treatment agent layer with a first chemical group; and an upper surface of a laminated structure formed by the substrate and the OLED unit is provided with a second surface treatment agent layer with a second chemical group; the first chemical group of the first surface treatment agent layer chemically reacts with the second chemical group of the second surface treatment agent layer to thereby form the water-oxygen-blocking encapsulation structure.

In an embodiment of the disclosure, the first chemical group at least includes one of —NCO, —NH2 and —OH, and the second chemical group at least includes one of —OH and —NH2.

In an embodiment of the disclosure, the outer surface of the pixel definition layer includes an upper surface of the pixel definition layer and an outer side surface of the pixel definition layer; the first surface treatment agent includes the silane coupling agent; and the second surface treatment agent includes a silicon-nitrogen compound (SiNx) and/or a silicon-oxygen compound.

In an embodiment of the disclosure, the OLED device further includes: a layer of silane coupling agent, arranged on the outer surface of the pixel definition layer; a hydrogen bonding is enabled between a —NH2/—OH group of the silicon-nitrogen compound/silicon-oxygen compound and an —X group of the X—Si(OR)3 to thereby enhance an adhesion force of the water-oxygen-blocking encapsulation structure.

In an embodiment of the disclosure, the water-oxygen-blocking encapsulation structure includes a sealant and a side surface treatment layer; the sealant is formed between the cover plate and the substrate and coats the OLED unit; and the side surface treatment layer is formed on an outer side surface of the sealant.

In an embodiment of the disclosure, the side surface treatment layer includes the silane coupling agent.

In an embodiment of the disclosure, a thickness of the side surface treatment layer is in a range from 10 nanometers (nm) to 30 nm, and a hydrophobic group of the silane coupling agent at least includes one of a long alkyl and a long alkyl epoxy ethyl.

An embodiment of the disclosure further provides a display device, including an OLED device, the OLED device including: a cover plate; a substrate, opposite to the cover plate; an OLED unit, arranged on a side of the substrate facing towards the cover plate; and a water-oxygen-blocking encapsulation structure based on a silane coupling agent, formed between the cover plate and the substrate and coating the OLED unit.

According to the method for encapsulating the OLED, the OLED device and the display device mentioned above, through the chemical action of the Bank and the SiNx/SiO2 (the silicon nitrogen compound/silicon oxygen compound) on the substrate and the silane coupling agent on the cover plate, the encapsulation adhesion and water and oxygen resistance characteristics are improved, the requirements of high adhesion and long lag time (low moisture permeability) required by OLED encapsulation are met, and water and oxygen entering the OLED due to insufficient adhesion and poor water and oxygen resistance are avoided, which leads to accelerated aging and failure of the OLED display device. Further, The interfacial adhesion of the frame encapsulation material is increased by forming chemical bonds or hydrogen bonds, and the water and oxygen resistance of the lateral encapsulation is improved through the method of the embodiment, thus effectively solving the material limitation problem which takes into account the requirements of high adhesion and excellent water and oxygen resistance, and realizing the thinning of the OLED display device.

In addition, in the embodiments of the disclosure, since a lateral surface treatment layer of Y—Si(OR)3 (silane coupling agent) material is arranged, the absorption of water and oxygen is reduced, the water diffusion coefficient is reduced, the encapsulating effect is improved. The failure risk of side encapsulating in the lateral encapsulating sealant in OLED rigid encapsulation is effectively reduced (water and oxygen diffusion of side encapsulating materials), and the material limitation problem of narrow frame and strong resistance to water and oxygen characteristics can also be solved. Also the method of manufacturing the lateral surface treatment layer material has a high compatibility with the current production flow, the absorption and diffusion coefficients of water and oxygen is effectively reduced at lower cost, the encapsulation effect is improved, and the unity of narrow frame encapsulating and good performance is achieved.

### BRIEF DESCRIPTION OF THE DRAWINGS

In order to explain technical solutions of the embodiments of the disclosure more clearly, the accompanying drawings used in the description of the embodiments will be briefly introduced below. It is clear that the accompanying drawings in the following description are only some embodiments of this disclosure, and for those of ordinary skill in the art, other drawings can be obtained according to these accompanying drawings without paying a creative labor.

FIG. 1 is a schematic structural diagram of a water-oxygen-blocking encapsulation structure according to an embodiment of the disclosure.

FIG. 2 is a schematic diagram of a curve illustrating a relationship between a delay time and an accumulated water flux of the water-oxygen-blocking encapsulation structure in FIG. 1.

FIG. 3 is a schematic flow chart of a method for encapsulating an OLED according to an embodiment of the disclosure.

FIG. 4 is a schematic structural diagram of an OLED device manufactured using a method for encapsulating an OLED according to an embodiment of the disclosure.

FIG. 5 is a schematic structural diagram of another OLED device manufactured using a method for encapsulating an OLED according to an embodiment of the disclosure.

FIG. 6 is a schematic diagram of a chemical reaction process according to an embodiment of the disclosure.

FIG. 7 is a schematic diagram of another chemical reaction process in an embodiment of the disclosure.

FIG. 8 is a schematic structural diagram of an OLED device according to another embodiment of the disclosure.

FIG. 9 is a schematic diagram of a Gel/Getter type encapsulation according to an embodiment of the disclosure.

FIG. 10 is a schematic diagram of Dam (a high viscosity frame glue) & fill (filling glue) type encapsulation according to an embodiment of the disclosure.

FIG. 11 is a schematic diagram of a face seal type encapsulation according to an embodiment of the disclosure.

FIG. 12 is a schematic diagram of a encapsulation structure of an OLED device according to an embodiment of the disclosure.

FIG. 13 is a schematic diagram of a encapsulation of a Dam &Fill side surface treatment layer according to an embodiment of the disclosure.

FIG. 14 is a schematic diagram of a encapsulation of a face seal side surface treatment layer according to an embodiment of the disclosure.

### DETAILED DESCRIPTION OF EMBODIMENTS

In order to make purposes, technical solutions and advantages of embodiments of the disclosure clearer, the technical solutions of the embodiments of the disclosure will be described clearly and completely with reference to the accompanying drawings in the embodiments of the disclosure. It is clear that the described embodiments are part of the disclosure, but not all of the disclosure. Based on the embodiments in the disclosure, all other embodiments obtained by ordinary technicians in this field without any creative labor belong to the protection scope of the disclosure.

The following embodiments are described by means of referring to the accompanying drawings so as to illustrate specific embodiments in which the disclosure can be implemented. Directional terms mentioned in the disclosure, such as “upper”, “lower”, “front”, “back”, “left”, “right”, “inner”, “outer”, “side”, etc., only refer to the directions of the accompanying drawings. Therefore, the directional terms are used to illustrate and explain the disclosure, but not to limit the disclosure.

The accompanying drawings and description are regarded as illustrative in nature and not restrictive. In the accompanying drawings, components with a similar structure are denoted by the same reference numerals. In addition, for the sake of understanding and convenience of description, a size and thickness of each component shown in the accompanying drawings are arbitrarily shown, but the disclosure is not limited thereto.

In addition, it should be noted that terms “first” and “second” in the specification and claims of the disclosure and the accompanying drawings are used to distinguish similar objects, and are not necessarily used to describe a specific order or sequence. It should be understood that the terms are interchangeable under appropriate circumstances, so that the embodiments of the disclosure described herein can be implemented in other order other than that illustrated or described herein. In addition, terms “including” and “having” and any variations thereof are intended to cover non-exclusive inclusion. For example, a process, a method, a system, a product or an apparatus that includes a series of steps or units need not be limited to those steps or units explicitly described herein, but may include other steps or units that are not explicitly described or inherent to these processes, methods, products or apparatuses. In addition, a term “on” means above or below a target component, and does not mean that it must be on top based on the gravity direction.

It also should be noted that division of the embodiments in the disclosure is only for convenience of description, and should not constitute a special limitation. The features in the embodiments can be combined and quoted from each other without contradiction.

In order to further explain technical means and efficacy adopted in the disclosure to achieve the intended purpose of the disclosure, a specific implementation, a structure, characteristics and efficacy of a method for encapsulating an OLED, an OLED device and a display device proposed according to this disclosure are described in detail hereinafter with reference to the accompanying drawings and preferred embodiments.

Specifically, the embodiments of the disclosure provide a method for encapsulating an OLED, an OLED device and a display device. The method for encapsulating an OLED includes the following steps: providing a cover plate; providing a substrate, where a side of the substrate is provided with an OLED unit; and forming a water-oxygen-blocking encapsulation structure between the cover plate and the substrate based on a silane coupling agent, where the water-oxygen-blocking encapsulation structure coats the OLED unit. In order to better understand the method for encapsulating the OLED, the OLED device and the display device according to the embodiments of the disclosure, several embodiments will be described in detail hereinafter.

### First Embodiment

At present, a main factor that restricts the development of the OLED industry and a main defect of the OLED display device is its short life, the main reason for which is that electrodes and OLED units (organic materials of light-emitting layer) constituting the OLED display device are very sensitive to pollutants, water vapor and oxygen in the atmosphere, and is prone to electrochemical corrosion in the environment containing water vapor and oxygen, and thereby a damage to the OLED display device is caused.

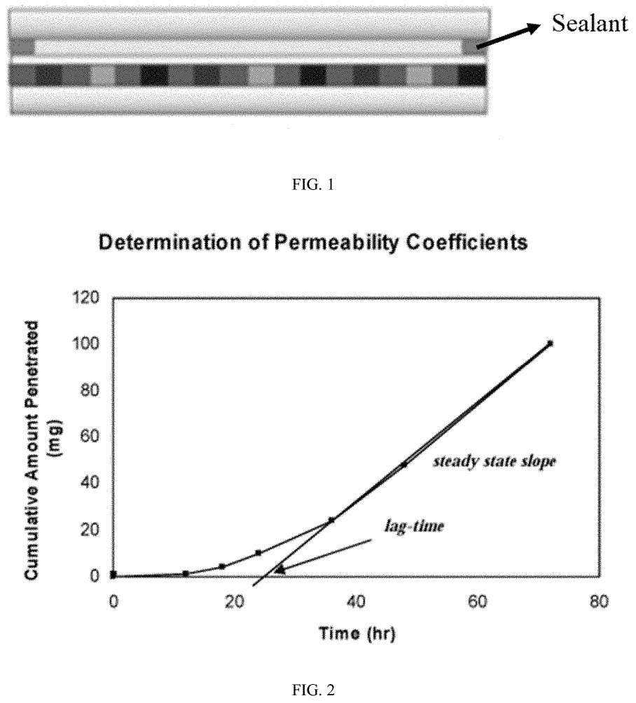

FIG. 1 is a schematic structural diagram of a water-oxygen-blocking encapsulation structure according to an embodiment of the disclosure. FIG. 2 shows a curve illustrating a relationship between a lag time (e.g., L represents a membrane thickness and D represents a membrane diffusion coefficient) and a water vapor transmission rate (WVTR, i.e., the cumulative amount penetrated) or a steady state water penetration flux (in this case, T represents time required for the steady state water penetrate flux, L represents a water penetrate path distance and D represents a water diffusion coefficient. Specifically, an ability to block water and oxygen is improved when Lag time(t)˜L\hat{ }2/6D and WVTR (g/m²*24 hr) is met.

Therefore, an embodiment of the disclosure provides a method for encapsulating an OLED, which is capable of preventing water vapor and oxygen from entering the OLED display device and improve the water and oxygen resistance of the OLED display device, thereby effectively preventing the accelerated aging and failure of the OLED display device.

The embodiment of the disclosure provides a method for encapsulating an OLED, which includes the following steps: providing a cover plate; providing a substrate, where a side of the substrate is provided with an OLED unit; and forming a water-oxygen-blocking encapsulation structure between the cover plate and the substrate based on a silane coupling agent, where the water-oxygen-blocking encapsulation structure coats the OLED unit.

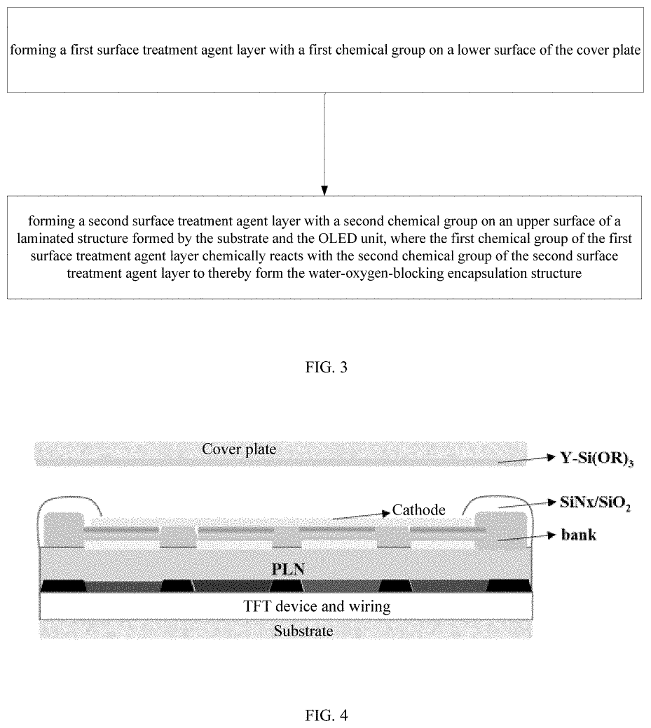

Specifically, as shown in FIG. 3, a step of forming a water-oxygen-blocking encapsulation structure between the cover plate and the substrate, includes: forming a first surface treatment agent layer with a first chemical group on a lower surface of the cover plate; and forming a second surface treatment agent layer with a second chemical group on an upper surface of a laminated structure formed by the substrate and the OLED unit, where the first chemical group of the first surface treatment agent layer chemically reacts with the second chemical group of the second surface treatment agent layer to thereby form the water-oxygen-blocking encapsulation structure.

Specifically, water-oxygen-blocking encapsulation for the OLED unit located between the cover plate and the substrate is achieved by the inorganic/organic layer using the above method.

Further, the water-oxygen-blocking encapsulation structure is used for prolonging a permeation path of air and moisture (Fick's First law), reducing a diffusion coefficient (Fick's second law) and prolonging the lag time. The water-oxygen-blocking encapsulation is used for preventing water vapor and oxygen from entering the OLED display device, and increasing an adhesive force of the water-oxygen-blocking encapsulation structure and a water flux of the water-oxygen-blocking encapsulation structure.

Further, the upper surface includes an outer surface of a pixel definition layer (also referred as a Bank) of the substrate. The first chemical group at least includes one of —NCO, —NH2 and —OH, and the second chemical group at least includes one of —OH and —NH2.

Further, the outer surface of the pixel definition layer includes an upper surface of the pixel definition layer and an outer side surface of the pixel definition layer. The first surface treatment agent includes the silane coupling agent (Y/X—Si(OR)3). The second surface treatment agent includes a silicon-nitrogen compound (SiNx) and/or a silicon-oxygen compound (for example, a silicon dioxide (SiO2)).

Further, the silane coupling agent chemically reacts with the silicon-nitrogen compound/silicon-oxygen compound to generate chemical bonds/hydrogen bonds, thereby increasing interfacial adhesion. The Bank, the silane coupling agent and the silicon-nitrogen compound/silicone compound can replace sealants (such as an epoxy resin sealant), and is capable of prolonging the lag time, improving the water and oxygen resistance of the OLED display device and reducing the thickness of the OLED display device.

Further, as shown in FIG. 4, an —OR group of the silane coupling agent performs a hydrogen binding adsorption with the cover plate, which is used for drying inorganic materials, and forming strong chemical bonds through a dehydration condensation reaction. The outer surface of the Bank is deposited with the silicon-nitrogen compound/silicon-oxygen compound by a low-temperature chemical vapor deposition (CVD) process, and the outer surface is provided with an —OH group. The —OH group is chemically bonded with the a —Y(—NCO) group of the silane coupling agent of a side of the cover plate, so as to enhance an adhesive force.

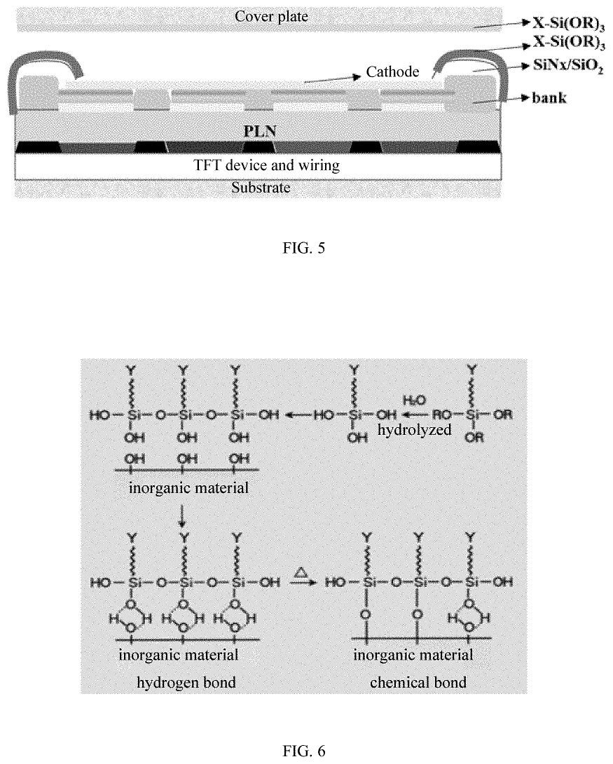

Further, as shown in FIG. 5, a layer of silane coupling agent (X—Si(OR)3) is added to the outer surface of the Bank. A —NH2/—OH group of the silicon-nitrogen compound/silicon-oxygen compound and an —X (for example, —NH2/—OH) group of the X—Si(OR)3 are subjected to hydrogen bonding to enhance an adhesion force.

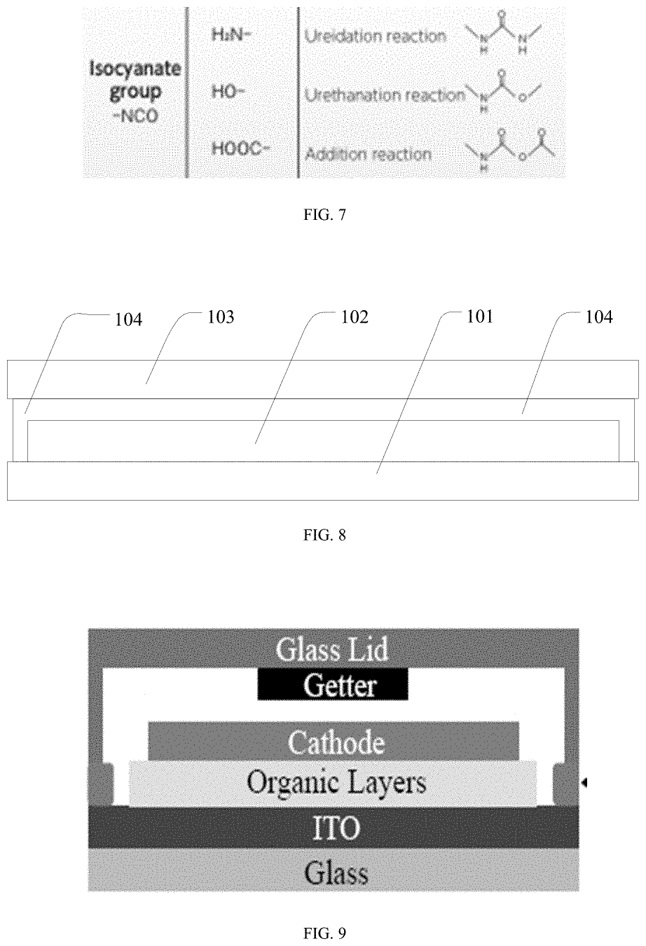

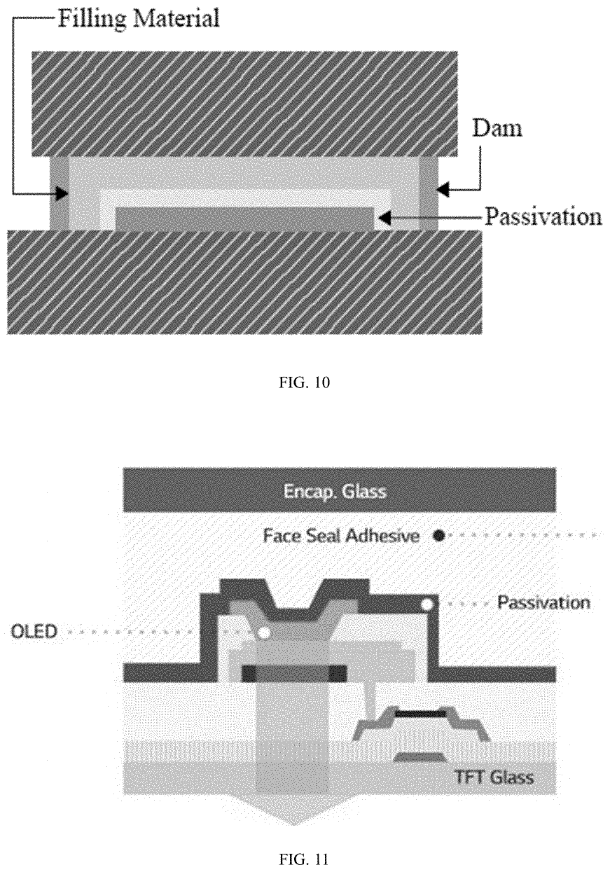

Specifically, as shown in FIGS. 6 and 7, for example, an epoxy resin sealant can be replaced with the bank, and the silane coupling agent and the SiNx/SiO2, such that Water diffusion coefficient (D) decreases, the water penetration path distance (L) increases, and the Lag time (t) increases. Therefore, the silane coupling agent is used to generate chemical bonds or hydrogen bonds between a surface of the cover plate and SiNx/SiO2 (a surface of the bank), thereby replacing the frame adhesive and increasing the interfacial adhesion force. A combination of the Bank, and the silane coupling agent and the SiNx/SiO2 is used to replace the epoxy resin sealant, which prolongs the lag time and improves the water and oxygen resistance, reducing the thickness of an OLED panel and realizing a thin screen of the OLED panel.

More specifically, for the cover plate, the —OR group of the silane coupling agent (Y/X—Si(OR)3) is close to the cover plate, and a —Y/X group of the silane coupling agent (Y/X—Si(OR)3) is far away from the cover plate. The silane coupling agent is decomposed into a silanol by water to perform a hydrogen binding adsorption on the surface of the cover plate. Then, inorganic materials are dried and dehydrated and condensed to form strong chemical bonds.

For the substrate side action, in one case, a SiNx/SiO2 is deposited on the surface of the Bank by a low temperature CVD, and the surface of the Bank has an —OH group. A chemical bonding is achieved between the —OH group on the SiNx/SiO2 and a —Y(—NCO) group on the cover plate, thereby enhancing the adhesion force. In another case, a SiNx/SiO2 is deposited on the surface of the Bank by a low temperature CVD, and a layer of X—Si(OR)3 (—X is —NH or —OH) is added to the surface of the Bank. A hydrogen bonding is achieved between a —NH2 group on the SiNx/SiO2 side and an —X (for example, —NH2) group on the cover plate, thereby enhancing the adhesion force.

In summary, the SiNx/SiO2 reacts with the Bank and the silane coupling agent to form an inorganic/organic layer, thereby prolonging the permeation path of air and moisture (Fick's First law), decreasing the diffusion coefficient (Fick's second law), prolonging the Lag time, and improving the water and oxygen resistance.

According to the method for encapsulating the OLED, through the chemical action of the Bank and the SiNx/SiO2 (the silicon nitrogen compound/silicon oxygen compound) on the substrate and the silane coupling agent on the cover plate, the encapsulation adhesion and water and oxygen resistance characteristics are improved, the requirements of high adhesion and long lag time (low moisture permeability) required by OLED encapsulation are met, and water and oxygen entering the OLED due to insufficient adhesion and poor water and oxygen resistance are avoided, which leads to accelerated aging and failure of the OLED display device. Further, The interfacial adhesion of the frame encapsulation material is increased by forming chemical bonds or hydrogen bonds, and the water and oxygen resistance of the lateral encapsulation is improved through the method of the embodiment, thus effectively solving the material limitation problem which takes into account the requirements of high adhesion and excellent water and oxygen resistance.

### Second Embodiment

As shown in FIG. 8, an embodiment of the disclosure provides an OLED device based on the first embodiment, which adopts the method for encapsulating the OLED described in the first embodiment, and the OLED device includes a substrate 101, an OLED unit 102, a cover plate 103 and a water-oxygen-blocking encapsulation structure 104 based on a silane coupling agent. Specifically, the OLED unit 102 is arranged on the substrate 101. The cover plate 103 is arranged on the OLED unit 102 and opposite to the substrate 101. The water-oxygen-blocking encapsulation structure 104 based on the silane coupling agent is formed between the cover plate and the substrate and coats the OLED unit 102, and is used for realizing water-oxygen-blocking encapsulation of the OLED unit 102.

Further, the water-oxygen-blocking encapsulation structure 104 is formed by a chemical reaction between a first chemical group of a first surface treatment agent layer on a lower surface of the cover plate 103 and a second chemical group of a second surface treatment agent layer on an upper surface of a laminated structure formed by the substrate 101 and the OLED unit 102. The substrate 101 has a pixel definition layer thereon. The upper surface includes an outer surface of a pixel defining layer of the substrate 101.

Further, the first chemical group at least includes one of —NCO, —NH2 and —OH, the second chemical group at least includes one of —OH and —NH2. The outer surface of the pixel definition layer includes an upper surface of the pixel definition layer and an outer side surface of the pixel definition layer.

Further, the first surface treatment agent includes a silane coupling agent (Y/X—Si(OR)3), and the second surface treatment agent includes a silicon nitrogen compound (SiNx) or silicon oxygen compound (SiO2) and the like.

In addition, a driving circuit, a control circuit and other technologies of the OLED device in the embodiment are relatively mature, which can be easily obtained and understood by those skilled in the art, and are not the focus of the disclosure, and will not be described in detail herein.

For the above OLED device, since a chemical action is performed between the Bank and SiNx/SiO2 (silicon nitrogen compound/silicon oxygen compound) on the substrate and the silane coupling agent on the cover plate, the encapsulating adhesion force and water and oxygen resistance characteristics are improved, the requirements of high adhesion and long lag time (low moisture permeability) required by the encapsulation of the OLED device are solved, and a problem that water and oxygen enter the OLED device due to insufficient adhesion and poor water and oxygen resistance is solved, which leads to accelerated aging and failure of the OLED device. The interfacial adhesion of the frame encapsulating material is increased by forming chemical bonds or hydrogen bonds, and the water and oxygen resistance of the lateral encapsulating is improved by the method of the embodiment, which effectively solves the material limitation problem that takes into account the requirements of high adhesion and excellent water and oxygen resistance, and the thinning of the OLED display device is also expected to be realized.

### Third Embodiment

An embodiment of the disclosure also provide a display device using the OLED device described in the second embodiment.

For example, the OLED device above mentioned, as a key component of the display device in the embodiment, is a core for normal display of the display device, and technologies such as a shell, a driving circuit, a control circuit, and an optical adjustment and an optimization of the display device are relatively mature, which can be easily obtained and understood by those skilled in the art, and will not be described in detail herein.

For the above display device, since a chemical action is performed between the Bank and SiNx/SiO2 (silicon nitrogen compound/silicon oxygen compound) on the substrate and the silane coupling agent on the cover plate, the encapsulating adhesion force and water and oxygen resistance characteristics are improved, the requirements of high adhesion and long lag time (low moisture permeability) required by the encapsulation of the OLED device are solved, and a problem that water and oxygen enter the OLED device due to insufficient adhesion and poor water and oxygen resistance is solved, which leads to accelerated aging and failure of the OLED device. The interfacial adhesion of the frame encapsulating material is increased by forming chemical bonds or hydrogen bonds, and the water and oxygen resistance of the lateral encapsulating is improved by the method of the embodiment, which effectively solves the material limitation problem that takes into account the requirements of high adhesion and excellent water and oxygen resistance, and the thinning of the OLED display device is also expected to be realized.

### Third Embodiment

An embodiment of the disclosure provides a method for encapsulating an OLED, which includes: providing a cover plate; providing a substrate, where a side of the substrate is provided with an OLED unit; and forming a water-oxygen-blocking encapsulation structure between the cover plate and the substrate based on a silane coupling agent, where the water-oxygen-blocking encapsulation structure coats the OLED unit. Specifically, the water-oxygen-blocking encapsulation structure includes a sealant and a side surface treatment layer, and the step of forming a water-oxygen-blocking encapsulation structure between the cover plate and the substrate based on a silane coupling agent, includes: forming the sealant between the cover plate and the substrate to coat the OLED unit; and forming the side surface treatment layer on an outer side surface of the sealant.

Specifically, the side surface treatment layer includes a Y—Si(OR)3 (silane coupling agent), where the side surface treatment layer is formed on the outer side surface of the sealant by a coating process.

Specifically, a thickness of the side surface treatment layer is in a range from 10 nanometers (nm) to 30 nm, and a hydrophobic group of the silane coupling agent at least includes one of a long alkyl and a long alkyl epoxy ethyl.

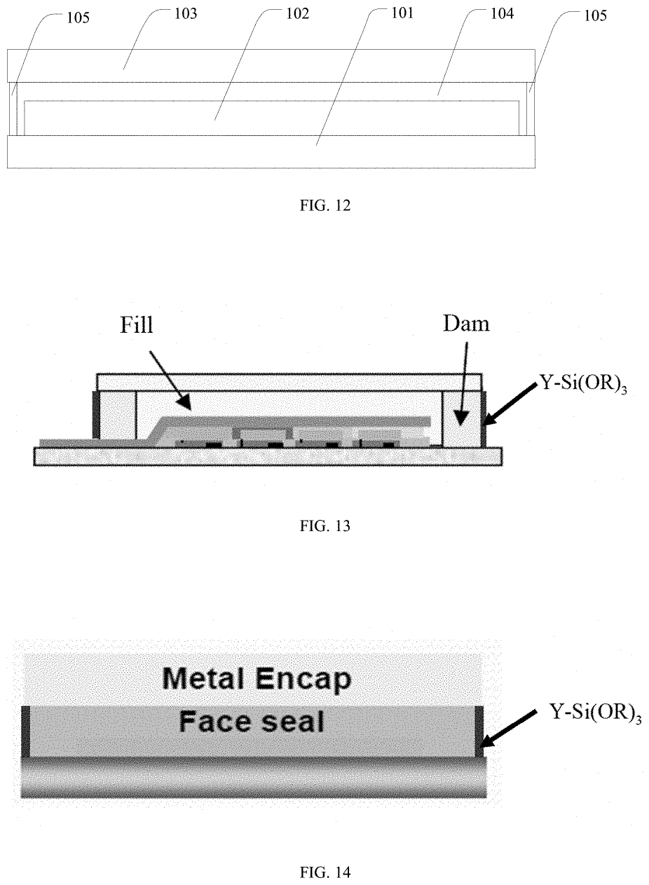

Correspondingly, as shown in FIG. 12, an embodiment of the disclosure provides an OLED device corresponding to the above the method for encapsulating the OLED, which includes a substrate 101; a cover plate 103 opposite to the substrate 101; an OLED unit 102 located between the substrate 101 and the cover plate 103; a sealant 104, configured to bond the substrate 101 and the cover plate 103 to each other so that the OLED unit 102 is sealed between the substrate 101 and the cover plate 103; a side surface treatment layer 105, arranged on an outer side surface of the sealant 104 and capable of improving the water and oxygen resistance of the encapsulating structure and preventing a light emitting layer of the OLED device from being affected by water vapor. That is to say, the sealant 104 and the side surface treatment layer 105 together form the water-oxygen-blocking encapsulation structure.

Further, the side surface treatment layer 105 is used to enhance the water and oxygen resistance of a side edge of the OLED device, and prevent water and oxygen from penetrating into a light-emitting layer of the OLED device to cause the deterioration thereof. The side surface treatment layer 105 is also used for thinning a frame of the OLED device to realize a narrow frame.

Further, the side surface treatment layer 105 includes a Y—Si(OR)3 (silane coupling agent), and is formed by a coating process.

Further, the —OR group of the Y—Si(OR)3 is decomposed into the —OH group when combining with water, and performs combine adsorption with hydrogen on a surface of the sealant. After drying treatment, a dehydration condensation reaction and chemical bonding occur, and thus the micropore defect is filled on the encapsulating material, thereby achieving water and oxygen resistance. The —Y group of the Y—Si(OR)3 has hydrophobic and anti-pollution characteristics, thereby reducing water and oxygen absorption and improving water resistance.

Further, a thickness of the side surface treatment layer 105 is in a range from 10 nm to 30 nm.

Further, a hydrophobic group of the silane coupling agent can reduce the water diffusion coefficient, and reduce water and oxygen absorption, thereby improving device performance and prolonging the service life of a corresponding OLED display panel.

Further, the hydrophobic group includes a long alkyl and a long alkyl epoxy ethyl.

Specifically, the long alkyl group of the silane coupling agent of the side surface treatment layer has hydrophobic effect, which can reduce water and oxygen absorption and water diffusion coefficient, thereby reducing the influence of water and oxygen on a performance of the OLED device, improving the performance of the OLED device, prolonging the life of a corresponding OLED display panel, and being beneficial to realize narrow frame of a display screen.

More specifically, as shown in FIG. 5 and FIG. 6, for example, for Dam & Fill and Face Seal encapsulation, the Y—Si(OR)3 is coated on sides thereof, and a molecular structure of Y—Si(OR)3 is as follows:

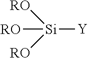

Specifically, —Y of the Y—Si(OR)3 is a hydrophobic group, such as a long alkyl, a long alkyl epoxy ethyl, etc. The —ORn group of the Y—Si(OR)3 is an —OH group or an alkyl group, etc. The —OR group of the Y—Si(OR)3 is decomposed into the —OH group when combining with water, and performs combine adsorption with hydrogen on a surface of the sealant. After drying treatment, a dehydration condensation reaction and chemical bonding occur, and thus the micropore defect is filled on the encapsulating material, thereby achieving water and oxygen resistance. The —Y group of the Y—Si(OR)3 has hydrophobic and anti-pollution characteristics, thereby reducing water and oxygen absorption and improving water resistance. Optionally, the thickness of the Y—Si(OR)3 layer is in a range from 10 nm to 30 nm. If the thickness is lower than 10 nm, it cannot achieve obvious efficacy. If the thickness is higher than 30 nm, there will be the risk of material cracking, and the cost will become higher.

In the above embodiments, since a lateral surface treatment layer of Y—Si(OR)3 material is arranged, the absorption of water and oxygen is reduced, the water diffusion coefficient is reduced, the encapsulating effect is improved, and the problems of accelerated aging and failure of the OLED display device caused by the diffusion of water and oxygen in the lateral encapsulating sealant in OLED rigid encapsulation, as well as the material limitation of narrow frame and strong resistance to water and oxygen characteristics are solved. Also the method of manufacturing the lateral surface treatment layer material has a high compatibility with the current production flow, the absorption and diffusion coefficients of water and oxygen is effectively reduced at lower cost, the encapsulation effect is improved, and the unity of narrow frame encapsulating and good performance is achieved.

In addition, a driving circuit, a control circuit and other technologies of the OLED device in the embodiment are relatively mature, which can be easily obtained and understood by those skilled in the art, and are not the focus of the disclosure, and will not be described in detail herein.

### Fifth Embodiment

An embodiment of the disclosure also provide a display device using the OLED device described in the fourth embodiment.

For example, the OLED device above mentioned, as a key component of the display device in the embodiment, is a core for normal display of the display device, and technologies such as a shell, a driving circuit, a control circuit, and an optical adjustment and an optimization of the display device are relatively mature, which can be easily obtained and understood by those skilled in the art, and will not be described in detail herein.

In the above embodiments, since a lateral surface treatment layer of Y—Si(OR)3 material is arranged, the absorption of water and oxygen is reduced, the water diffusion coefficient is reduced, the encapsulating effect is improved, and the problems of accelerated aging and failure of the OLED display device caused by the diffusion of water and oxygen in the lateral encapsulating sealant in OLED rigid encapsulation, as well as the material limitation of narrow frame and strong resistance to water and oxygen characteristics are solved. Also the method of manufacturing the lateral surface treatment layer material has a high compatibility with the current production flow, the absorption and diffusion coefficients of water and oxygen is effectively reduced at lower cost, the encapsulation effect is improved, and the unity of narrow frame encapsulating and good performance is achieved.

Terms such as “in some embodiments” and “in various embodiments” are used repeatedly, these terms do not generally refer to the same embodiment, however, these terms can also refer to the same embodiment. The words “including”, “having” and “including” are synonyms unless the context shows other meanings.

The above are only a preferred embodiments of the disclosure, and are not used to limit the in any form. Although the disclosure has been disclosed with specific embodiments as above, it is not intended to limit the disclosure. Any person familiar with this profession can make some changes or modifications to equivalent embodiments with equivalent changes by using the technical contents disclosed above without departing from the technical solutions of the disclosure. Without departing from the contents of the technical solutions of the disclosure, any simple modifications, equivalent changes and modifications made to the above embodiments according to the technical essence of the disclosure still fall within the scope of the technical solutions of the disclosure.

What is claimed is:

1. A method for encapsulating an organic light-emitting diode (OLED), comprising:
providing a cover plate;
providing a substrate, wherein a side of the substrate is provided with an OLED unit,
forming a water-oxygen-blocking encapsulation structure between the cover plate and the substrate based on a silane coupling agent, wherein the water-oxygen-blocking encapsulation structure coats the OLED unit.

2. The method according to claim 1, wherein forming a water-oxygen-blocking encapsulation structure between the cover plate and the substrate based on a silane coupling agent, comprises:
forming a first surface treatment agent layer with a first chemical group on a lower surface of the cover plate; and
forming a second surface treatment agent layer with a second chemical group on an upper surface of a laminated structure formed by the substrate and the OLED unit;
wherein the first chemical group of the first surface treatment agent layer chemically reacts with the second chemical group of the second surface treatment agent layer to thereby form the water-oxygen-blocking encapsulation structure.

3. The method according to claim 2, wherein the upper surface comprises an outer surface of a pixel definition layer of the substrate;
wherein the first chemical group at least comprises one of —NCO, —NH2 and —OH, and the second chemical group at least comprises one of —OH and —NH2.

4. The method according to claim 3, wherein the outer surface of the pixel definition layer comprises an upper surface of the pixel definition layer and an outer side surface of the pixel definition layer;
wherein the first surface treatment agent comprises the silane coupling agent;
wherein and the second surface treatment agent comprises a silicon-nitrogen compound (SiNx) and/or a silicon-oxygen compound.

5. The method according to claim 4, further comprising:
adding a layer of silane coupling agent to the outer surface of the pixel definition layer, so as to enable a hydrogen bonding between a —NH2/—OH group of the silicon-nitrogen compound/silicon-oxygen compound and an —X group of the X—Si(OR)3 to thereby enhance an adhesion force of the water-oxygen-blocking encapsulation structure.

6. The method according to claim 1, wherein the water-oxygen-blocking encapsulation structure comprises a sealant and a side surface treatment layer;
wherein forming a water-oxygen-blocking encapsulation structure between the cover plate and the substrate based on a silane coupling agent, comprises:
forming the sealant between the cover plate and the substrate to coat the OLED unit; and
forming the side surface treatment layer on an outer side surface of the sealant.

7. The method according to claim 6, wherein the side surface treatment layer comprises the silane coupling agent;
wherein the side surface treatment layer is formed on the outer side surface of the sealant by a coating process.

8. The method according to claim 7, wherein a thickness of the side surface treatment layer is in a range from 10 nanometers (nm) to 30 nm, and a hydrophobic group of the silane coupling agent at least comprises one of a long alkyl and a long alkyl epoxy ethyl.

9. An OLED device, comprising:
a cover plate;
a substrate, opposite to the cover plate;
an OLED unit, arranged on a side of the substrate facing towards the cover plate; and
a water-oxygen-blocking encapsulation structure based on a silane coupling agent, formed between the cover plate and the substrate and coating the OLED unit.

10. The OLED device according to claim 9, wherein a lower surface of the cover plate is provided with a first surface treatment agent layer with a first chemical group; and an upper surface of a laminated structure formed by the substrate and the OLED unit is provided with a second surface treatment agent layer with a second chemical group;
wherein the first chemical group of the first surface treatment agent layer chemically reacts with the second chemical group of the second surface treatment agent layer to thereby form the water-oxygen-blocking encapsulation structure.

11. The OLED device according to claim 10, wherein the first chemical group at least comprises one of —NCO, —NH2 and —OH, and the second chemical group at least comprises one of —OH and —NH2.

12. The OLED device according to claim 11, wherein the outer surface of the pixel definition layer comprises an upper surface of the pixel definition layer and an outer side surface of the pixel definition layer;
wherein the first surface treatment agent comprises the silane coupling agent; and
wherein the second surface treatment agent comprises a silicon-nitrogen compound (SiNx) and/or a silicon-oxygen compound.

13. The OLED device according to claim 12, further comprising:
a layer of silane coupling agent, arranged on the outer surface of the pixel definition layer;
wherein a hydrogen bonding is enabled between a —NH2/—OH group of the silicon-nitrogen compound/silicon-oxygen compound and an —X group of the X—Si(OR)3 to thereby enhance an adhesion force of the water-oxygen-blocking encapsulation structure.

14. The OLED device according to claim 9, wherein the water-oxygen-blocking encapsulation structure comprises a sealant and a side surface treatment layer;
wherein the sealant is formed between the cover plate and the substrate and coats the OLED unit; and
wherein the side surface treatment layer is formed on an outer side surface of the sealant.

15. The OLED device according to claim 14, wherein the side surface treatment layer comprises the silane coupling agent.

16. The OLED device according to claim 15, wherein a thickness of the side surface treatment layer is in a range from 10 nanometers (nm) to 30 nm, and a hydrophobic group of the silane coupling agent at least comprises one of a long alkyl and a long alkyl epoxy ethyl.

17. A display device, comprising an OLED device, the OLED device comprising:
a cover plate;
a substrate, opposite to the cover plate;
an OLED unit, arranged on a side of the substrate facing towards the cover plate; and
a water-oxygen-blocking encapsulation structure based on a silane coupling agent, formed between the cover plate and the substrate and coating the OLED unit.
